(19) United States
(12) Patent Application Publication
(10) Pub. No.: US 2009/0249162 A1
(43) Pub. Date: Oct. 1, 2009

(54) ERROR CORRECTION SYSTEM USING THE DISCRETE FOURIER TRANSFORM

(76) Inventors: Cen Jung Tjhai, Plymouth (GB); Marcel Adrian Ambroze, Plymouth (GB); Mohammed Zaki Ahmed, Plymouth (GB)

Correspondence Address: Martin Tomlinson, The Old Coach House, Tristford, Harberton, Totnes, TQ9 7RZ, omitted

(21) Appl. No.: 12/057,781

(22) Filed: Mar. 28, 2008

(51) Int. Cl. H03M 13/29; G06F 11/00

(52) U.S. Cl. 714/755; 714/E11.001

(57) ABSTRACT

A system of determining unknown symbols of an error correcting code using the Discrete Fourier Transform (DFT) with arithmetic corresponding to the number field of the error correcting code, including complex numbers. Encoder and decoder configurations are described. Parallel generation of independent parity check equations, simultaneous solution of unknown symbols generating, or regenerating a codeword of the error correcting code.

### FIELD OF THE INVENTION

The field of the invention is that of applications using error correction coding.

### BACKGROUND TO THE INVENTION

This invention relates to the encoding and decoding of codewords of error correcting codes which are subject to erasures or errors and provides a means of efficiently encoding codewords, or efficiently determining unknown symbols of a codeword, or determining candidate sets of unknown symbols of a codeword as a step in error correction decoding. It also provides a means of encoding and decoding error correcting codes that use codewords with complex number coefficients. That is, the invention also provides a means of encoding and decoding analog error correcting codes.

### BRIEF SUMMARY OF THE INVENTION

The invention is concerned with providing an efficient system of encoding codewords of an error correcting code or decoding codewords of an error correcting code by determining unknown symbols of a codeword. The error correcting code may use symbols with values from a Galois field [1, 2] in the traditional manner or the error correcting code may use symbols with values from the field of complex numbers. In either case the invention provides a means of encoding or decoding codewords from the error correcting code in an efficient manner. Applications include communication, storage or information systems that use a channel or medium characterised by erasures [3, 7, 8, 9] or the deletion of symbols. Error correction systems require the determination of unknown symbols of each codeword in carrying out encoding and decoding and the invention provides an efficient means of encoding and decoding.

Unknown symbols of a codeword of an error correcting code may arise from the action of a channel or may arise from the decoder postulating that some symbols should be declared unknown due to their unreliability. Such decoders feature correction of unknown symbols as a step in the decoding procedure [4, 5, 6]. Standard error correction systems use an error correcting code characterised by parameters n, the length of the code in symbols, k the number of information symbols and d the Hamming distance [1, 2]. Standard methods can determine d−1 unknown symbols by using procedures that have a complexity proportional to n³. One such method is the method originated by Gauss for solving n−k linear equations. As a result of the cubic dependancy with codeword length, standard methods of determining unknown symbols are not practical for long codewords. The invention provides a means of determining the unknown symbols of a codeword with a complexity proportional to (d−2)×n and is therefore much more efficient. Moreover codewords having complex number coefficients may be encoded or decoded by the invention.

### BRIEF SUMMARY OF THE DRAWINGS

FIG. 1 shows a block diagram of a communication system, storage system or information system using an error correcting code. Data is encoded into codewords of the error correcting code by the encoder prior to transmission over the communication channel, or storage using a data storage medium, or for access by an information system. After trans-mission over the communication system, or data retrieval from the data storage medium, or information system, unknown symbols from each codeword are determined by the decoder.

FIG. 2 shows the encoder for the error correcting code and features for each input vector containing k information symbols, buffering of the input vector, calculation of a parity check equation, using this equation to calculate a parity symbol, and updating of the input vector followed by calculation of a different parity check equation and using this equation to calculate a different parity symbol, and updating of the input vector. The procedure repeating until all parity symbols have been determined and the resulting updated input vector is a codeword of the error correcting code. By using the list of the parity symbols, the controller produces the correct sequence of operations as outlined above to produce an encoded codeword.

FIG. 3 shows the decoder for the error correcting code and features for each input vector, buffering of the input vector, repeated calculation of parity check equations followed by calculation of unknown symbols, and repeated updating of the input vector until all unknown symbols have been determined. With the last updating of the input vector, the input vector becomes the original codeword of the error correcting code, unless the error correcting capability of the code has been exceeded. By using the list of the unknown symbols contained in each input vector, a controller produces the correct sequence of operations necessary to determine the unknown symbols and controls the production of a codeword of the error correcting code from the input vector.

### DETAILED DESCRIPTION OF THE DRAWINGS

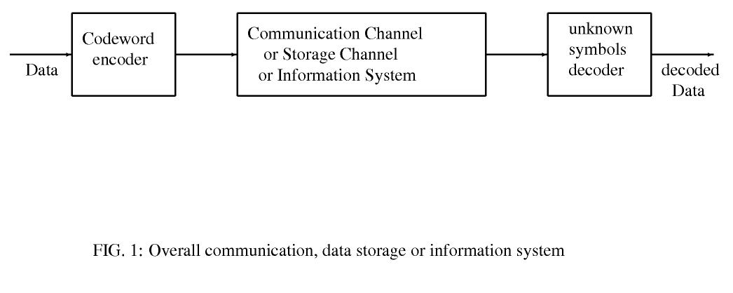

FIG. 1 shows a generic block diagram of a communication system, storage system or information system using an error correcting code. An error correcting code is commonly described as having codewords of length n symbols comprising k information symbols and n−k parity symbols [1, 2]. The invention provides a means of encoding and decoding and also provides flexibility and efficiency. As well as error correcting codes with codeword coefficients from a Galois Field, error correcting codes with codeword coefficients from the field of complex numbers may be encoded or decoded using the invention. As shown in FIG. 1 input data is encoded into codewords of an error correcting code by the encoder prior to transmission over the communication channel, or storage using a data storage medium or for use in an information system. After transmission over the communication system or data retrieval from the data storage medium, or retrieval from an information system, erased, deleted or otherwise unknown symbols are determined by the decoder.

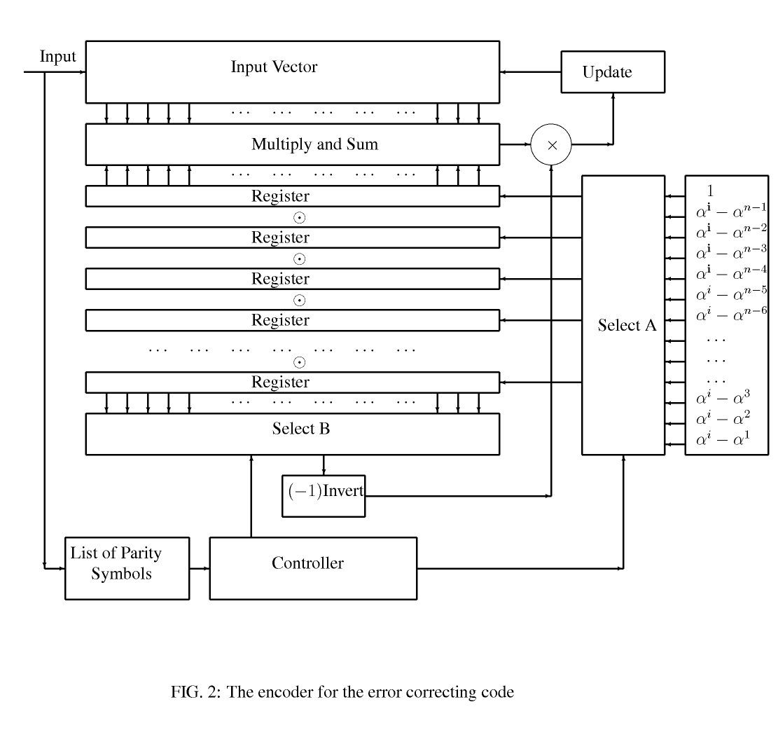

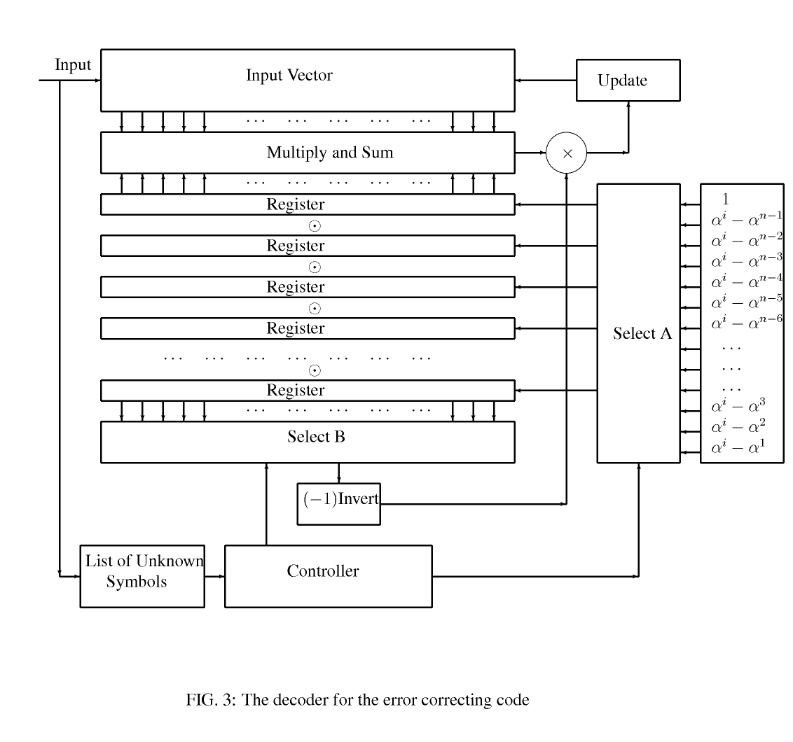

In FIG. 1 the encoder generates n−k parity check symbols from k information symbols. FIG. 2 is a detailed diagram of the encoder which generates any set of n−k parity symbols from k known symbols. Since the set of n−k parity check symbols is included in the class of sets of any n−k unknown symbols it is clear that the encoder is a special case of the decoder, shown in FIG. 3, which determines all of the unknown symbols from any set of n−k unknown symbols, given k known symbols.

The minimum Hamming distance between codewords d is equal to n−k+1 and is the reason why the code is capable of regenerating any set of n−k symbols [1, 2]. Each symbol of the code takes values from a field [1]. Error correcting codes are based on a Galois Field having q elements, denoted as GF(q), but the invention may be used with any field including the field of complex numbers. For any Galois Field there is a well known [1] class of codes known as Bose and Ray-Chaudhuri Hocquenghem (BCH) codes. For any other field the corresponding codes are referred to here as analog Bose and Ray-Chaudhuri Hocquenghem (BCH) codes.

For Galois Fields, BCH codes are defined by a generator polynomial g(x) given by

$$g ( x ) = {\prod }_{i = β}^{β + n - k - 1} ( x - {α}^{i} ) \qquad ( 1 )$$

where α is a primitive root of GF(q), or equivalently, a primitive root of unity, and β is a code parameter, an integer between 0 and n−1.

For other fields, analog BCH codes are defined by a generator polynomial g(x) given by

$$g ( x ) = {\prod }_{i = β}^{β + n - k - 1} ( x - {α}^{i} ) \qquad ( 2 )$$

where α is a primitive root of unity, and β is a code parameter, an integer between 0 and n−1.

In either case, codewords, c(x) are given by g(x).d(t) where d(t) is a polynomial of degree less than k having coefficients equal to the information symbols. For every generator polynomial there is a parity check polynomial, h(x) such that g(x).h(x)=xⁿ−1, and g(x).h(x)=0 modulo xⁿ−1.

The efficient realisation of an encoder and decoder for BCH error correcting codes or analog BCH error correcting codes is the subject of this invention. The encoder is shown in FIG. 2 and the decoder is shown in FIG. 3. The theoretical basis for the invention lies with properties of the discrete Fourier transform. The discrete Fourier Transform using arithmetic from a Galois Field is known as the Mattson-Solomon polynomial and is documented for example in the text-book by MacWilliams and N. J. A. Sloane [1].

From the parity check polynomial h(x) it follows that c(x).h(x)=γ(x)=0 modulo xⁿ−1.

γ(x)=γ₀+γ₁x+γ₂x²+γ₃x³ . . . +γₙ₋₁xⁿ⁻¹=0 (3)

and so each coefficient γᵢ=0 for i=0 to n−1 producing n linear, parity check equations. The n linear equations are not all independent but they do allow for any n−k unknown coefficients of c(x) to be solved. In other words any combination of n−k symbols may be erased from a codeword and the erasures may be determined by solving n−k linear equations.

Galois fields and BCH codes are considered first. For any polynomial, f(x) of degree less that n and with coefficients which are elements of GF(q) the Mattson-Solomon polynomial F(z) is given by

$$F ( z ) = {\sum }_{i = 0}^{n - 1} f ( {α}^{- i} ) {z}^{i} \qquad ( 4 )$$

The original polynomial f(x) may be obtained from its Mattson-Solomon polynomial via the inverse Mattson-Solomon polynomial

$$f ( x ) = {n}^{- 1} {\sum }_{i = 0}^{n - 1} F ( {α}^{i} ) {x}^{i} \qquad ( 5 )$$

The factor n⁻¹ is the multiplicative inverse of n in GF(q). For q=2^{m}, n⁻¹=1

Any codeword c(x) has a Mattson-Solomon polynomial C(z). The parity check polynomial h(x) has a Mattson-Solomon polynomial H(z). Just as c(x)h(x)=0 modulo xⁿ−1; in the Mattson-Solomon domain C(z)\textcircled{·}H(z)=0 where \textcircled{·} represents a multiplication of the coefficients corresponding to the same powers of z.

$$C ( z ) ⊙ H ( z ) = {\sum }_{i = 0}^{n - 1} {C}_{i} {H}_{i} {z}^{i} = 0 \qquad ( 6 )$$

For each non zero coefficient of C(z) the corresponding coefficient of H(z) is zero and vice versa.

The BCH code provides the basis which can be used to solve for n−k unknown symbols. Let the positions of the unknown symbols be defined by λᵢ where =0 to n−k−1 and let the codeword containing the unknown symbols be denoted as ĉ(x) with coefficients arbitrarily set in the unknown symbol positions. There is a polynomial m_{λ}_{ⱼ}(x) that when multiplied by the parity check polynomial h(x) produces a polynomial which is denoted as s_{λ}_{ⱼ}(x) and has the property that the coefficients of x^{n-λ}^{ᵢ}=0 for i=0 to n−k−2, i≠j. Since c(x).h(x)=0, it follows that ĉ(x).m_{λ}_{ⱼ}(x).h(x)=0 as well.

### Substituting

ĉ(x).m_{λ}_{ⱼ}(x).h(x)=ĉ(x)s_{λ}_{ⱼ}(x)=0 (7)

The polynomial ĉ(x) has coefficients equal to the coefficients of the codeword c(x) except in the unknown symbol positions. The x⁰ coefficient given by equation (7) is given by

$${\hat{c}}_{{λ}_{j}} \cdot {s}_{{λ}_{j} ( n - {λ}_{j} )} + {\sum }_{i = 0 , i \neq {λ}_{j}}^{n - 1} {\hat{c}}_{i} \cdot {s}_{{λ}_{j} ( n - i )} = 0 \qquad ( 8 )$$

Since none of the unknown coefficients of ĉ(x) feature in equation (8), this equation may be used to solve for the unknown symbol in position λⱼ,

$${\hat{c}}_{{λ}_{j}} = - {s}_{{λ}_{j} ( n - {λ}_{j} )}^{- 1} {\sum }_{i = 0 , i \neq {λ}_{j}}^{n - 1} {\hat{c}}_{i} \cdot {s}_{{λ}_{j} ( n - i )} \qquad ( 9 )$$

The polynomial s_{λ}_{ⱼ}(x) is derived using the inverse Mattson-Solomon polynomial. Since the error correcting code is a BCH code, the coefficients of C(z) are zero for consecutive powers of z from β through to β+n−k−1, where β is a code parameter, an integer constant between 0 and n−1. For i greater than zero, the polynomial uᵢ(x) is used to denote the inverse Mattson-Solomon polynomial of z−α^{n-λ}^{ᵢ}. For the case i=0, u₀(x) is the inverse Mattson-Solomon polynomial of z^{β}. In general, for i>0

$${u}_{i} ( x ) = {n}^{- 1} {\sum }_{m = 0}^{n - 1} ( {α}^{m} - {α}^{n - {λ}_{i}} ) {x}^{m} \qquad ( 10 )$$

The important point is that the coefficient of x^{n-λ}^{ᵢ} of uᵢ(x) is equal to zero and uᵢ(x) is a parity check polynomial of c(x).

Correspondingly,

c(x)uᵢ(x)=0 (11)

If the coefficient of x^{λ}^{ᵢ} of c(x) is unknown due to there being an unknown symbol in position λᵢ of the codeword, this will not affect the evaluation of the coefficient of x⁰ in equation (11). A practical point is that as c(x)uᵢ(x)=0, uᵢ(x) may be multiplied by any non zero field element, such as n and so the term n⁻¹ may be ignored in equation (10) leading to the simplification for uᵢ(x):

$${u}_{i} ( x ) = {\sum }_{m = 0}^{n - 1} ( {α}^{m} - {α}^{n - {λ}_{i}} ) {x}^{m} \qquad ( 12 )$$

For the solution of the unknown symbol in position λₙ₋ₖ₋₁ the polynomial s_{λ}_{_{n−k−1}}(x) is given by

s_{λ}_{_{n−k−1}}(x)=u₀(x)\textcircled{·}u₁(x)\textcircled{·}u₂(x) . . . \textcircled{·}uₙ₋ₖ₋₂(x) (13)

The coefficient ĉ_{λ}_{_{n−k−1}} is determined using equation (9).

For the general case, in order to obtain the solution of the unknown symbol in position λⱼ the polynomial s_{λ}_{ⱼ}(x) is given by

$${s}_{{λ}_{j}} ( x ) = {\prod }_{i = 0 , i \neq j}^{n - k - 1} {u}_{i} ( x ) \qquad ( 14 )$$

and the coefficient ĉ_{λ}_{ⱼ} is determined using equation (9).

Fields other than Galois Fields and analog BCH codes are now considered. For any polynomial, f(x) of degree less that n and with coefficients which are elements of a field with

$$f ( x ) = {\sum }_{i = 0}^{n - 1} {f}_{i} {x}^{i} \qquad ( 15 )$$

the discrete Fourier Transform of f(x) is given by

$${F}_{k} = {\sum }_{i = 0}^{n - 1} {f}_{i} {α}^{- ik} \qquad ( 16 )$$

where α is a primitive root of unity. For the field of complex numbers

$$α = {e}^{\frac{j 2 π}{n}} ,$$

where j=\sqrt{−1}, and

$${F}_{k} = {\sum }_{i = 0}^{n - 1} {f}_{i} {e}^{- \frac{j 2 π i k}{n}} \qquad ( 17 )$$

This equation may be simplified by noticing that substituting

$${e}^{- \frac{j 2 π}{n}}$$

for the variable y in the polynomial f(y)

$${F}_{k} = f ( {e}^{- \frac{j2π k}{n}} ) \qquad ( 18 )$$

Furthermore by defining a polynomial

$$F ( z ) {\sum }_{k = 0}^{n - 1} {F}_{k} {z}^{k} \qquad$$

then

$$F ( z ) = {\sum }_{k = 0}^{n - 1} f ( {e}^{- \frac{j 2 π k}{n}} ) {z}^{k} \qquad ( 19 )$$

Replacing

$${e}^{\frac{j 2 π}{n}}$$

with α, equation (19) becomes

$$F ( z ) = {\sum }_{k = 0}^{n - 1} f ( {α}^{- k} ) {z}^{k} \qquad ( 20 )$$

It will be seen that this is the same as the Mattson-Solomon polynomial given by equation (4).

Similarly the polynomial, f(x) of degree less that n and with coefficients which are elements of a field may be obtained from the inverse discrete Fourier Transform of the Fourier coefficients Fₖ and is given by

$${f}_{i} = \frac{1}{n} {\sum }_{k = 0}^{n - 1} {F}_{k} ( {α}^{i k} ) \qquad ( 21 )$$

where α is a primitive root of unity. It may be seen that

$$f ( x ) = \frac{1}{n} {\sum }_{i = 0}^{n - 1} F ( {α}^{i} ) {x}^{i} \qquad ( 22 )$$

and that this is the same as the inverse Mattson-Solomon polynomial given by equation (5).

Accordingly any codeword c(x) from an analog BCH code with coefficients from any field has Fourier coefficients given by a polynomial C(z) using equation (19). The parity check polynomial h(x) has Fourier coefficients given by a polynomial H(z). Just as c(x)h(x)=0 modulo xⁿ−1; in the Fourier domain C(z)\textcircled{·}H(z)=0 where \textcircled{·} represents a multiplication of the coefficients corresponding to the same powers of z.

$$C ( z ) ⊙ H ( z ) = {\sum }_{i = 0}^{n - 1} {C}_{i} {H}_{i} {z}^{i} = 0 \qquad ( 23 )$$

For each non zero coefficient of C(z) the corresponding coefficient of H(z) is zero and vice versa.

Given k coefficients of a codeword c(x) from an analog BCH code, and these coefficients may be in any k positions, the n−k parity check coefficients are determined by n−k parity check equations given by the inverse Fourier transform. As for BCH codes, for i greater than zero, the polynomial uᵢ(x) is used to denote the inverse Fourier transform of Fourier coefficients given by the polynomial F(z)=z−α^{n-λ}^{ᵢ}. For the case i=0, u₀(x) is the inverse Fourier transform of z^{β}, where β is an integer constant between 0 and n−1 and is defined by the error correcting code. In general, for i>0

$${u}_{i} ( x ) = {n}^{- 1} {\sum }_{m = 0}^{n - 1} ( {α}^{m} - {α}^{n - {λ}_{i}} ) {x}^{m} \qquad ( 24 )$$

For the field of complex numbers

$${u}_{i} ( x ) = {n}^{- 1} {\sum }_{m = 0}^{n - 1} ( {e}^{\frac{j 2 π m}{n}} - {e}^{\frac{j2π ( n - {λ}_{i} )}{n}} ) {x}^{m} \qquad ( 25 )$$

The important point is that the coefficient of x^{n-λ}^{ᵢ} of uᵢ(x) is equal to zero and uᵢ(x) is a parity check polynomial of the codeword c(x).

As before, to determine the solution of the unknown symbol in position, say, λₙ₋ₖ₋₁ the parity check polynomial s_{λ}_{_{n−k−1}}(x) is given by

s_{λ}_{_{n−k−1}}(x)=u₀(x)\textcircled{·}u₁(x)\textcircled{·}u₂(x) . . . \textcircled{·}uₙ₋ₖ₋₂(x) (26)

and the coefficient ĉ_{λ}_{_{n−k−1}} is determined using equation (9) using arithmetic from the field in question. For the general case, since s_{λ}_{ⱼ}(x)c(x)=0, the parity check polynomial s_{λ}_{ⱼ}(x) may be multiplied by any non zero field element. Consequently in practice, it is convenient to multiply uᵢ(x) by the factor n to eliminate the term n⁻¹ in equations (24) and (25).

In the encoder shown in FIG. 2, which may be used for all types of fields, β=0 and u₀(x) is the all 1's vector. The list of positions of the parity check symbols are stored and used by the Controller to direct Select A to select which of the uᵢ(x) vectors will be stored in the Registers prior to being multiplied together to derive s_{λ}_{ⱼ}(x). From a practical viewpoint it is convenient to initialise the input vector with zeros in the positions of the parity check symbols so that

$${\sum }_{i = 0 , i \neq {λ}_{j}}^{n - 1} {\hat{c}}_{i} \cdot {s}_{{λ}_{j} ( n - i )} = {\sum }_{i = 0}^{n - 1} {\hat{c}}_{i} \cdot {s}_{{λ}_{j} ( n - i )} \qquad ( 27 )$$

and now the coefficient ĉ_{λ}_{ⱼ} is determined using the equation

$${\hat{c}}_{{λ}_{j}} = - {s}_{{λ}_{j} ( n - {λ}_{j} )}^{- 1} {\sum }_{i = 0}^{n - 1} {\hat{c}}_{i} \cdot {s}_{{λ}_{j} ( n - i )} \qquad ( 28 )$$

With this initialisation the derived parity check equation s_{λ}_{ⱼ}(x) may be used directly to determine the unknown symbol as shown in FIG. 2 so that the output of Multiply and Sum is equal to the result of equation (27). Under direction of the Controller, Select B selects the coefficient of s_{λ}_{ⱼ}(x), s_{λ}_{ⱼ}_{(n-λ}_{ⱼ}₎ which is multiplied by −1 and inverted, as shown in FIG. 2, and multiplied by the output of Multiply and Sum to produce the solution for the unknown symbol in position λⱼ, ĉ_{λ}_{ⱼ}. The codeword stored in Input Vector is updated with this calculated coefficient using Update as shown in FIG. 2.

For the encoder shown in FIG. 2, the calculation of parity symbols is a serial procedure with each of the n−k parity check equations s_{λ}_{ⱼ}(x) being used to derive each of the n−k parity check symbols which are used to update the input vector to form a codeword of the error correcting code after all n−k parity check symbols have been derived. As each of the parity check equations s_{λ}_{ⱼ}(x) for j=0 to n−k−1 does not involve any other parity check symbols, it is possible to calculate all parity symbols at the same time, in parallel.

In the decoder shown in FIG. 3, which may be used for Galois and non Galois fields, β=0 and u₀(x) is the all 1's vector. The list of positions of the unknown symbols are stored and used by the Controller to direct Select A to select which of the uᵢ(Z) vectors will be stored in the Registers prior to being multiplied together to derive s_{λ}_{ⱼ}(x). As in the encoder, the input vector has been initialised with zeros in the positions of the unknown symbols so that equation (27) and equation (28) are valid and each parity check equation s_{λ}_{ⱼ}(x) may be used directly to determine each unknown symbol. In FIG. 3 the output of Multiply and Sum is equal to the result of equation (27). Under direction of the Controller, Select B selects the coefficient of s_{λ}_{ⱼ}(x), s_{λ}_{ⱼ}_{(n-λ}_{ⱼ}₎ which is multiplied by −1 and inverted, as shown in FIG. 3, and multiplied by the output of Multiply and Sum to produce the solution for the unknown symbol in position λⱼ, ĉ_{λ}_{ⱼ} and the codeword stored in Input Vector is updated with this calculated coefficient using Update as shown in FIG. 3.

For the decoder shown in FIG. 3, the calculation of unknown symbols is a serial procedure with each of the n−k parity check equations, s_{λ}_{ⱼ}(x), being used to derive each of the n−k unknown symbols which are used to update the input vector to form the codeword of the error correcting code after all n−k unknown symbols have been derived.

In another embodiment of the invention, suited to high speed applications, all of the n−k parity check equations, s_{λ}_{ⱼ}(x) for j=0 through to n−k−1 and given by equation (14), may be determined in parallel. Also, since each equation provides a solution to each of the unknown symbols and is independent of all of the other unknown symbols, all of the n−k unknown symbols may be determined simultaneously. It is clear that this may be done for either the encoder or the decoder.

In a further embodiment of the invention which is suited to very high speed applications, the parity check equations for sets of unknown symbols may be pre-calculated and stored in one or more look up tables. Given a set of unknown symbols, the required parity check equations to solve for these symbols may be accessed from one or more of the look up tables.

In another embodiment of the invention which is suited to low complexity applications, the parity check equation s_{λ}_{_{n−k−1}}(x) which provides the solution of the unknown symbol in position λₙ₋ₖ₋₁ is derived first and is given by equation (26) above. Equation (9) is then used to determine the unknown symbol in position λₙ₋ₖ₋₁ producing the coefficient ĉ_{λ}_{_{n−k−1}}. This coefficient may be substituted into ĉ(x) so that ĉ(x) now only contains n−k−1 unknown symbols. The unknown symbol in position λₙ₋ₖ₋₂ may be solved using the polynomial s₋₁(x) given by

s₋₁(x)=u₀(x)\textcircled{·}u₁(x)\textcircled{·}u₂(x) . . . \textcircled{·}uₙ₋ₖ₋₃(x) (29)

and by using equation (9). It will be noticed that s₋₁(x) consists of the same product terms as s_{λ}_{_{n−k−1}}(x) except that the last product term, uₙ₋ₖ₋₂(x) is omitted. Consequently there is no necessity to carry out the products again to derive s₋₁(x) because it has already been derived as an intermediate step in deriving s_{λ}_{_{n−k−1}}(x).

The coefficient ĉ_{λ}_{_{n−k−2}} is now determined and ĉ(x) updated by using the polynomial s₋₂(x) given by

s₋₂(x)=u₀(x)\textcircled{·}u₁(x)\textcircled{·}u₂(x) . . . \textcircled{·}uₙ₋ₖ₋₃(x) (30)

As before there is no necessity to derive this equation again because it has already been derived as an intermediate step. It may be further observed that in deriving s_{λ}_{_{n−k−1}}(x) all of the other n−k−1 required parity check equations may be produced in turn and stored for later use. The procedure repeats until all of the unknown symbols have been solved with the final result that ĉ(x)=c(x). It is clear that this embodiment of the invention may be applied to both the encoder and the decoder.

### EXAMPLES

In the first example, the coefficients of codewords are from the Galois field GF(11) whose non zero elements are generated by powers of the primitive root α modulo 11, and for the prime number, p=11, α is equal to 2:

TABLE 1
All 10 Non zero Galois Field elements of GF(11) for α = 2

| symbol | αⁱ | αⁱ modulo p |
|---|---|---|
| α⁰ | 1 | 1 |
| α¹ | 2 | 2 |
| α² | 4 | 4 |
| α³ | 8 | 8 |
| α⁴ | 16 | 5 |
| α⁵ | 32 | 10 |
| α⁶ | 64 | 9 |
| α⁷ | 128 | 7 |
| α⁸ | 256 | 3 |
| α⁹ | 512 | 6 |

For GF(11), n=10, and the codeword is of length 10 symbols. Consider an example of a codeword with ĉ(x)=3x⁴+2x⁵+7x⁶+ĉ₇x⁷+ĉ₈x⁸+ĉ₉x⁹ where ĉ₇, ĉ₈ and ĉ₉ are parity symbols, and the other coefficients of ĉ(x) are zero. The parity symbol positions are λ₀=7, λ₁=8 and λ₂=9. β=0 and the parity check equation, u₀(x), is the all 1's vector. Using equation (12), the parity check equation u₁(x) is given by

$${u}_{1} ( x ) = {\sum }_{j = 0}^{n - 1} ( {α}^{j} - {α}^{10 - 7} ) {x}^{j} = {\sum }_{j = 0}^{n - 1} ( {α}^{j} - {α}^{3} ) {x}^{j} \qquad ( 31 )$$

after evaluation

u₁(x)=(α⁰−α³)+(α¹−α³)x+(α²−α³)x²+(α³−α³)x³+(α⁴−α³)x⁴+ . . . (32)

and

u₁(x)=α²+α⁴x+α⁷x²+α³x⁴+α¹x⁵+x⁶+ . . . (33)

The parity check equation u₂(x) is given by

$${u}_{2} ( x ) = {\sum }_{j = 0}^{n - 1} ( {α}^{j} - {α}^{10 - 8} ) {x}^{j} = {\sum }_{j = 0}^{n - 1} ( {α}^{j} - {α}^{2} ) {x}^{j} \qquad ( 34 )$$

after evaluation

u₂(x)=(α⁰−α²)+(α¹−α²)x+(α²−α²)x²+(α³−α²)x³+(α⁴−α²)x⁴+ . . . (35)

and

u₂(x)=α³+α⁶x+α²x³+x⁴+α⁹x⁵+α⁴x⁶+ . . . (36)

The parity check equation to solve for the parity symbol in position λ₂=9, s₉(x)=u₀(x)\textcircled{·}u₁(x)\textcircled{·}u₂(x) and

s₉(x)=α⁵x+α³x⁴+x⁵+α⁴x⁶+ . . . (37)

The product s₉(x)c(x)=0 and for the coefficient of x⁰

3α⁴+2+7α³+ĉ₉=0 (38)

and

4+2+1+ĉ₉=0 (39)

and ĉ₉=7×−1=7×10=4
Referring to FIG. 2 the List of Parity Symbols contains the numbers 7, 8, and 9. The Controller directs Select A to store u₀(x), u₁(x) and u₂(x) in the respective Registers which are multiplied, symbol by symbol, to produce s₉(x) which is input to Multiply and Sum. The other input to Multiply and Sum is ĉ(x) with parity coefficients set ĉ₇=0, ĉ₈=0, and ĉ₉=0. The output of Multiply and Sum is 7 which is input to the multiplier. The Controller directs Select B to select the coefficient of x¹ of s₉(x) which is 1. This is negated and Invert produces at its output 10 which is also input to the multiplier. The product output is 4 which Update uses to update coefficient ĉ₉ of the Input Vector.

Similarly for the solution of ĉ₈, the parity check equation u₃(x) is required and given by

u₃(x)=α⁵+αx²+α⁹x³+α⁸x⁴+α³x⁵+α⁷x⁶+ . . . (40)

and the parity check equation required to solve for the parity symbol in position 8, s₈(x) u₀(x)\textcircled{·}u₁(x)\textcircled{·}u₃(x) is

s₈(x)=α⁷+α⁸x²+αx⁴+α⁴x⁵+α⁷x⁶+ . . . (41)

The product s₈(x)c(x)=0 and for the coefficient of x⁰

3α⁷+2α⁴+7α+α⁸ĉ₈=0 (42)

and

10+10+3+α⁸ĉ₈=0 (43)

and

$${\hat{c}}_{8} = - \frac{1}{{α}^{8}} = 10 \times {α}^{2} = 7.$$

Referring to FIG. 2 the Controller directs Select A to store u₀(x), u₁(x) and u₃(x) in the respective Registers which are multiplied, symbol by symbol, to produce s₈(x) which is input to Multiply and Sum. The other input to Multiply and Sum is ĉ(x) with parity coefficients set ĉ₇=0 and ĉ₈=0. The output of Multiply and Sum is 1 which is input to the multiplier. The Controller directs Select B to select the coefficient of x² of s₈(x) which is α⁸. This is negated and Invert produces at its output 7 which is also input to the multiplier. The product output is 7 which Update uses to update coefficient ĉ₈ of the Input Vector.

Similarly the parity check equation required to solve for the parity symbol in position 7, s₇(x)=u₀(x)\textcircled{·}u₂(x)\textcircled{·}u₃(x) and after solving gives ĉ₇=10 and the complete codeword after all of the updating of coefficients is

c(x)=ĉ(x)=3x⁴+2x⁵+7x⁶+10x⁷+7x⁸+4x⁹ (44)

As a check, determining u₀(x)c(x), the coefficient of x⁰ is 3+2+7+10+7+4=33=0.

As an example of the invention being used as a decoder, consider that the above codeword is retrieved from an information system as

ĉ(x)=ĉ₄x⁴+2x⁵+ĉ₆x⁶+10x⁷+7x⁸+4x⁹ (45)

The unknown symbol positions are λ₀=4, and λ₁=6. To determine the coefficient ĉ₆, it is sufficient to determine the parity check equation s_{λ}_{₁}(x)=u₀(x)\textcircled{·}u₁(x) and

$${s}_{{λ}_{1}} ( x ) = {\sum }_{j = 0}^{n - 1} ( {α}^{j} - {α}^{10 - 4} ) {x}^{j} = {\sum }_{j = 0}^{n - 1} ( {α}^{j} - {α}^{6} ) {x}^{j} \qquad ( 46 )$$

and after evaluation

s₆(x)=α⁸+α²x+α⁹x²+x³+α⁷x⁴+x⁵+αx⁷+ . . . (47)

As before, the product s₆(x)ĉ(x)=0 and for the coefficient of x⁰

2+ĉ₆α⁷+10α⁵+7α⁹+4α²=0 (48)

giving 2+7ĉ₆+100+42+16=0 and 7ĉ₆=5 and

$${\hat{c}}_{6} = \frac{{α}^{4}}{{α}^{7}} = {α}^{7} = 7.$$

Referring to FIG. 3 the List of Unknown Symbols contains the numbers 4 and 6. The Controller directs Select A to store u₀(x) and u₁(x) in the respective Registers which are multiplied, symbol by symbol, to produce s₆(x) which is input to Multiply and Sum. The other input to Multiply and Sum is ĉ(x) with unknown coefficients set, ĉ₄=0 and ĉ₆=0. The output of Multiply and Sum is 6 which is input to the multiplier. The Controller directs Select B to select the coefficient of x⁴ of s₆(x) which is α⁷. This is negated and Invert produces at its output 3 which is also input to the multiplier. The product output is 7 which Update uses to update coefficient c₆ of the Input Vector.

To solve for the unknown symbol ĉ₄, s_{λ}_{₀}(x) is required and given by s_{λ}_{₀}(x) u₀(x)\textcircled{·}u₂(x) and

$${s}_{{λ}_{0}} ( x ) = {\sum }_{j = 0}^{n - 1} ( {α}^{j} - {α}^{10 - 6} ) {x}^{j} = {\sum }_{j = 0}^{n - 1} ( {α}^{j} - {α}^{4} ) {x}^{j} \qquad ( 49 )$$

and after evaluation

s₄(x)=α⁷+α³x+α⁵x²+α⁸x³+α⁴x⁵+α²x⁶+ . . . (50)

The product s₄(x)ĉ(x)=0 and for the coefficient of x⁰

10+4+8+10+ĉ₄α²=0 (51)

giving 10+α²ĉ₄=0 and

$${\hat{c}}_{4} = \frac{1}{{α}^{2}} = {α}^{8} = 3$$

the finally updated codeword ĉ(x)=3x⁴+2x⁵+7x⁶+10x⁷+7x⁸+4x⁹ and is equal to the original codeword c(x). Referring to FIG. 3 the Controller directs Select A to store u₀(x) and u₂(x) in the respective Registers which are multiplied, symbol by symbol, to produce s₄(x) which is input to Multiply and Sum. The other input to Multiply and Sum is ĉ(x) with unknown coefficient set, ĉ₄=0. The output of Multiply and Sum is 10 which is input to the multiplier. The Controller directs Select B to select the coefficient of x⁶ of s₄(x) which is α². This is negated and Invert produces at its output 8 which is also input to the multiplier. The product output is 3 which Update uses to update coefficient ĉ₄ of the Input Vector. With the last update the Input Vector becomes 3x⁴+2x⁵+7x⁶+10x⁷+7x⁸+4x⁹ which is equal to the original codeword c(x).

The second example is for a binary BCH code of length n=15, with codewords generated by the generator polynomial g(x)=(1+x³+x⁴)(1+x). The Galois field is GF(2⁴) generated by the primitive root oz which is a root of the primitive polynomial 1+x+x⁴ so that 1+α+α⁴=0 and the Galois field consists of the following table of 15 field elements, plus the element, 0.

TABLE 2
All 15 Non zero Galois Field elements of GF(16)

| symbol | αⁱ | modulo | 1 + α + α⁴ | |
|---|---|---|---|---|
| α⁰ = | 1 | | | |
| α¹ = | | α¹ | | |
| α² = | | | α² | |
| α³ = | | | | α³ |
| α⁴ = | 1+ | α | | |
| α⁵ = | | α+ | α² | |
| α⁶ = | | | α²+ | α³ |
| α⁷ = | 1+ | α+ | | α³ |
| α⁸ = | 1+ | | α² | |
| α⁹ = | | α+ | | α³ |
| α¹⁰ = | 1+ | α+ | α² | |
| α¹¹ = | | α+ | α²+ | α³ |
| α¹² = | 1+ | α+ | α²+ | α³ |
| α¹³ = | 1+ | | α²+ | α³ |
| α¹⁴ = | 1+ | | | α³ |

An example of a codeword from the binary BCH code is

c(x)=x+x³+x⁴+x⁶+x⁸+x⁹+x¹⁰+x¹¹ (52)

and consider that in a communication system, the codeword is received with erasures in positions in λ₀=5, λ₁=0 and λ₂=8 so that the received codeword is

ĉ(x)=ĉ₀+x+x³+x⁴+ĉ₅x⁵+x⁶+ĉ₈x⁸+x⁹+x¹⁰+x¹¹ (53)

Referring to FIG. 3, Select A selects the parity check equation, u₀(x), the all 1's vector to be stored in the Register. The parity check equation u₁(x) has zero in position n−λ₀=n−5 and is given by

$${u}_{1} ( x ) = {\sum }_{j = 0}^{n - 1} ( {α}^{j} - {α}^{15 - 5} ) {x}^{j} = {\sum }_{j = 0}^{n - 1} ( {α}^{j} - {α}^{10} ) {x}^{j} \qquad ( 54 )$$

In FIG. 3, Select A selects u₁(x) to be stored in the corresponding Register. The polynomial u₁(x) is

u₁(x)=(α⁰−α¹⁰)+(α¹−α¹⁰)x+(α²−α¹⁰)x²+(α³−α¹⁰)x³+(α⁴−α¹⁰)x⁴+ . . . (55)

and noting that the base field is 2 so that −1=1,

u₁(x)=α⁵+α⁸x+α⁴x²+α¹²x³+α²x⁴+x⁵+α⁷x⁶+α⁶x⁷+αx⁸+α¹³x⁹+α¹⁴x¹¹+α³x¹²+α⁹x¹³+α¹¹x¹⁴ (56)

The parity check equation u₂(x) has zero in position n−λ₁=n−0 and is given by

$${u}_{2} ( x ) = {\sum }_{j = 0}^{n - 1} ( {α}^{j} - {α}^{15 - 0} ) {x}^{j} = {\sum }_{j = 0}^{n - 1} ( {α}^{j} - 1 ) {x}^{j} \qquad ( 57 )$$

after evaluation

$${u}_{2} ( x ) = {α}^{4} x + {α}^{8} {x}^{2} + {α}^{14} {x}^{3} + α {x}^{4} + {α}^{10} {x}^{5} + {α}^{13} {x}^{6} + {α}^{9} {x}^{7} + {α}^{2} {x}^{8} + {α}^{7} {x}^{9} + {α}^{5} {x}^{10} + {α}^{12} {x}^{11} + {α}^{11} {x}^{12} + {α}^{6} {x}^{13} + {α}^{3} {x}^{14} \qquad ( 58 )$$

Referring to FIG. 3, Select A will select this polynomial to be stored in the corresponding Register.

The parity check equation s₈(x) which gives the solution for coefficient ĉ₈ is s₈(x)=u₀(x)\textcircled{·}u₁(x)\textcircled{·}u₂(x). Multiplying each of the corresponding coefficients together of the polynomials u₀(x), u₁(x) and u₂(x) produces

$${s}_{8} ( x ) = {α}^{12} x + {α}^{12} {x}^{2} + {α}^{11} {x}^{3} + {α}^{3} {x}^{4} + {α}^{10} {x}^{5} + {α}^{5} {x}^{6} + {x}^{7} \vert {α}^{10} {x}^{8} \vert {α}^{5} {x}^{9} \vert {α}^{11} {x}^{11} \vert {α}^{14} {x}^{12} \vert {x}^{13} \vert {α}^{14} {x}^{14} \qquad ( 59 )$$

Referring to FIG. 3, s₈(x) will be input to Multiply and Sum. It should be noted that the parity check equation s₈(x) has non binary coefficients even though the codeword is binary and the solution to the parity check equation has to be binary.

Evaluating the coefficient of x⁰ of s₈(x)ĉ(x) gives α¹⁴+α¹⁴+α¹¹+α⁵+ĉ₈+α⁵+α¹⁰+α³=0 which simplifies to α¹¹+ĉ₈+α¹⁰+α³=0. Using Table 2 gives

(α+α²+α³)+ĉ₈+(1+α+α²)+α³=0

and ĉ₈=1. Referring to FIG. 3, Select B produces from s₈(x) the value of the coefficient of x⁷ which is 1 and when inverted this is also equal to 1. The output of the Multiply and Add is 1 producing a product of 1, which is used by Update to update ĉ₈=1 in the Input Vector ĉ(x).

The parity check equation s₀(x) which gives the solution for coefficient ĉ₀ is s₀(x)=u₀(x)\textcircled{·}u₁(x)\textcircled{·}u₃(x) with u₃(x) given by

$${u}_{3} ( x ) = {\sum }_{j = 0}^{n - 1} ( {α}^{j} - {α}^{15 - 8} ) {x}^{j} = {\sum }_{j = 0}^{n - 1} ( {α}^{j} - {α}^{7} ) {x}^{j} \qquad ( 60 )$$

after evaluation

$${u}_{3} ( x ) = {α}^{9} + {α}^{14} x + {α}^{12} {x}^{2} + {α}^{4} {x}^{3} + {α}^{3} {x}^{4} + {α}^{13} {x}^{5} + {α}^{10} {x}^{6} + {α}^{11} {x}^{8} + {x}^{9} + {α}^{6} {x}^{10} + {α}^{8} {x}^{11} + {α}^{2} {x}^{12} + {α}^{5} {x}^{13} + α {x}^{14} \qquad ( 61 )$$

and s₀(x) is now

$${s}_{0} ( x ) = {α}^{14} + {α}^{5} x + α {x}^{2} + α {x}^{3} + {α}^{5} {x}^{4} + {α}^{13} {x}^{5} + {α}^{2} {x}^{6} + {α}^{12} {x}^{8 } + {α}^{13} {x}^{9} + {α}^{7} {x}^{11} + {α}^{5} {x}^{12} + {α}^{14} {x}^{13} + {α}^{12} {x}^{14} \qquad ( 62 )$$

Referring to FIG. 3, s₀(x) is input to Multiply and Sum. Evaluating the coefficient of x⁰ of s₀(x)ĉ(x) gives

α¹⁴ĉ₀+α¹²+α⁵+α⁷+α¹³+α²+α¹³+α⁵=0

which simplifies to α¹⁴ĉ₀+α¹²+α⁷+α²=0. Using Table 2 gives

α¹⁴ĉ₀+(1+α+α²+α³)+(1+α+α³)+α²=0

and ĉ₀=0. Referring to FIG. 3, Select B produces from s₀(x) the coefficient of x⁰ which is α¹⁴ and when negated, Invert produces oz at its output. The output of the Multiply and Add is 0 producing a product of 0, which is used by Update to update ĉ₀=0 in the Input Vector ĉ(x).

In order to solve for 5 the parity check equation s₅(x)=u₀(x)\textcircled{·}u₂(x)\textcircled{·}u₃(x) is used, and s₅(x) is given by

$${s}_{5} ( x ) = {α}^{3} x + {α}^{5} {x}^{2} + {α}^{3} {x}^{3} + {α}^{4} {x}^{4} + {α}^{8} {x}^{5} + {α}^{8} {x}^{6} + {α}^{13} {x}^{8} + {α}^{7} {x}^{9} + {α}^{11} {x}^{10} + {α}^{5} {x}^{11} + {α}^{13} {x}^{12} + {α}^{11} {x}^{13} + {α}^{4} {x}^{14} \qquad ( 63 )$$

Referring to FIG. 3, s₅ (x) is input to Multiply and Sum. Evaluating the coefficient of x⁰ of s⁵(x)ĉ(x) gives

α⁴+α¹³+α⁵+α¹¹ĉ₅+α⁷+α⁸+α⁸+α⁴=0

which simplifies to α¹¹ĉ₅+α¹³+α⁵+α⁷=0. Using Table 2 gives

α¹¹ĉ₅+(1+α²+α³)+(α+α²)+(1+α+α³)=0

and ĉ₅=0. Referring to FIG. 3, Select B produces from s₅(x) the coefficient of x¹⁰ which is α¹¹ and when negated, Invert produces a 4. The output of the Multiply and Add is 0 producing a product of 0, which is used by Update to update ĉ₅=0 in the Input Vector ĉ(x) giving

ĉ(x)=x+x³+x⁴+x⁶+x⁸+x⁹+x¹⁰+x¹¹

It is apparent that the final, updated Input Vector, ĉ(x) is equal to the original codeword c(x).

The third example is for an analog BCH code of length n=8, with codewords generated by the Discrete Fourier Transform using oz equal to the 8^{th} root of unity and with complex codeword coefficients. The powers of α are given in the following table of complex field elements.

TABLE 3

| | |
|---|---|
| αⁱ | ${e}^{\frac{ji 2 π}{8}}$ |

| | | |
|---|---|---|
| α⁰ = | 1 | j0 |
| α¹ = | 0.7071 | j0.7071 |
| α² = | 0 | j1 |
| α³ = | −0.7071 | j0.7071 |
| α⁴ = | −1 | j0 |
| α⁵ = | −0.7071 | −j0.7071 |
| α⁶ = | 0 | −j1 |
| α⁷ = | 0.7071 | −j0.7071 |

All 8 distinct powers of α = ${e}^{\frac{j 2 π}{8}}$

Each codeword from the analog BCH code consists of n=8 symbols where each coefficient is a complex number. In this particular example the code is chosen with 3 parity check coefficients and 5 information symbols. In the following, for brevity, the complex numbers are truncated and only two decimal places are shown. Consider the example codeword

$$\hat{c} ( x ) = {\hat{c}}_{0} + {\hat{c}}_{1} x + {\hat{c}}_{2} {x}^{2} + ( 0.41 - 0.63 j ) {x}^{3} - ( 0.72 - 0.28 j ) {x}^{4} + ( 1.45 - 0.85 j ) {x}^{5} - ( 1.28 - 1.1 j ) {x}^{6} + ( 0.96 - 1.34 j ) {x}^{7} \qquad ( 64 )$$

The first three coefficients are the parity check symbols and referring to FIG. 2. the example codeword is stored as the Input Vector with the initialisation ĉ₀=0, ĉ₁=0 and ĉ₂=0. The List of Parity Symbols contains λ₀=0, λ₁=1 and λ₂=2. For λ₀=0, Controller uses Select A to select the vectors α⁰, αⁱ−α⁸⁻¹ and αⁱ−α⁸⁻², where i=0 through to 7. The vectors correspond to u₀(x), u₂(x) and u₃(x). These are stored in each respective Register and multiplied together to produce the vector corresponding to the overall parity check equation s₀(x) which is used to calculate ĉ₀. s₀(x)=u₀(x)\textcircled{·}u₂(x)\textcircled{·}u₃(x) where u₀(x) is

u₀(x)=1+x+x²+x³+x⁴+x⁵+x⁶+x⁷ (65)

and u₂(x) is

$${u}_{2} ( x ) = ( 0.29 + 0.70 j ) + 1.41 jx - ( 0.70 - 1.70 j ) {x}^{2} - ( 1.41 - 1.41 j ) {x}^{3} - ( 1.70 - 0.70 j ) {x}^{4} - 1.41 {x}^{5} - ( 0.70 + 0.29 j ) {x}^{6} \qquad ( 66 )$$

and u₃(x) is

$${u}_{3} ( x ) = 1 + j + ( 0.70 + 1.70 j ) x + 2 {x}^{2} - ( 0.70 - 1.70 j ) {x}^{3} - ( 1 - j ) {x}^{4} - ( 0.70 - 0.29 j ) {x}^{5} + ( 0.70 + 0.29 j ) {x}^{7} \qquad ( 67 )$$

The resulting product s₀(x) is

$${s}_{0} ( x ) = - ( 0.41 - j ) - ( 2.41 - j ) x - ( 3.41 + 1.41 j ) {x}^{2} - ( 1.41 + 3.41 j ) {x}^{3} - ( 1 - 2.41 j ) {x}^{4} + ( 1 - 0.41 j ) {x}^{5} \qquad ( 68 )$$

Since s₀(x)ĉ(x)=0, evaluating the coefficient of x⁰ gives

$$0 = - ( 0.41 - j ) {\hat{c}}_{0} - ( 2.41 - j ) ( 0.96 - 1.34 j ) + ( 3.41 + 1.41 j ) ( 1.28 - 1.1 j ) - ( 1.41 + 3.41 j ) ( 1.45 - 0.85 j ) + ( 1 - 2.41 j ) ( 0.72 - 0.28 j ) + ( 1 - 0.41 j ) ( 0.41 - 0.63 j ) \qquad$$

and after evaluation

(0.41−j)ĉ₀=0.1−0.28j (69)

and

ĉ₀=(0.1−0.28j)(0.35+0.85j)=0.27−0.01j (70)

Referring to FIG. 2, the polynomials u₀(x), u₂(x) and u₃(x) are selected by Select A and each is stored in a Register and multiplied together as shown to produce s₀(x) which is input to Multiply and Sum. The other input to Multiply and Sum is the Input Vector, ĉ(x) with initialisation, ĉ₀=0, ĉ₁=0 and ĉ₂=0. The output of Multiply and Sum is 0.1−0.28j which is input to the multiplier. Select B selects from s₀(x), the coefficient of x⁰ which is −0.41+j. This is negated and inverted to produce at the output of Invert (0.35+0.85j) which is also input to the multiplier. As shown in FIG. 2, the result of the product, which in this case is 0.27−0.01j, is used by Update to update the coefficient ĉ₀ of the Input Vector.

In similar fashion the other two coefficients of c(x), ĉ₁ and ĉ₂, are derived and used to update the Input Vector to produce finally the codeword of the analog BCH code:

$$c ( x ) = \hat{c} ( x ) = ( 0.27 - 0.01 j ) - ( 2.70 + 0.34 j ) x + ( 1.61 + 1.79 j ) {x}^{2} + ( 0.41 - 0.63 j ) {x}^{3} - ( 0.72 - 0.28 j ) {x}^{4} + ( 1.45 - 0.85 j ) {x}^{5} - ( 1.28 - 1.1 j ) {x}^{6} + ( 0.96 - 1.34 j ) {x}^{7}$$

Consider that in an information system, this codeword is partially retrieved with unknown symbols in positions λ₀=4, λ₁=5 and λ₂=7 so that the received codeword is

$$\hat{c} ( x ) = ( 0.27 - 0.01 j ) - ( 2.70 + 0.34 j ) x + ( 1.61 + 1.79 j ) {x}^{2} + ( 0.41 - 0.63 j ) {x}^{3} + {\hat{c}}_{4} {x}^{4} + {\hat{c}}_{5} {x}^{5} - ( 1.28 + 1.1 j ) {x}^{6} + {\hat{c}}_{7} {x}^{7}$$

Referring to FIG. 3 the List of Unknown Symbols contains λ₀=4, λ₁=5 and λ₂=7. For λ₀=4, Controller uses Select A to select the polynomial coefficient vectors α⁰, αⁱ−α⁸⁻⁵ and αⁱ−α⁸⁻⁷ corresponding to u₀(x), u₂(x) and u₃(x). These are stored in each respective Register and multiplied together to produce s₄(x):

$${s}_{4} ( x ) = - 1.41 j - 0.58 {x}^{2} + 1.41 {jx}^{4} - ( 2 - 2 j ) {x}^{5} - 3.41 {x}^{6} - ( 2 + 2 j ) {x}^{7} \qquad ( 71 )$$

This is input to Multiply and Sum. The other input to Multiply and Sum is the Input Vector, ĉ(x) with unknown coefficients initialised, ĉ₄=0, ĉ₅=0 and ĉ₇=0. The output of Multiply and Sum is 0.4+1.02j which is input to the multiplier. Select B selects from s₄(x), the coefficient of x⁴ which is 1.41j. This is negated and inverted to produce at the output of Invert, 0.71j, which is also input to the multiplier. As shown in FIG. 3, the result of the product, which in this case is −0.72+0.28j, is used by Update to update the coefficient ĉ₄ of the Input Vector.

For λ₁=5, Controller uses Select A to select the polynomial coefficient vectors α⁰, αⁱ−α⁸⁻⁴ and αⁱ−α⁸⁻⁷ corresponding to u₀(x), u₁(x) and u₃(x). These are stored in each respective Register and multiplied together to produce s₅(x):

$${s}_{5} ( x ) = ( 0.58 - 1.41 j ) - ( 1 + 0.41 j ) {x}^{2} - ( 0.41 + j ) {x}^{3} - ( 1.41 - 0.58 j ) {x}^{5} - ( 2.41 + j ) {x}^{6} - ( 1 + 2.41 j ) {x}^{7} \qquad ( 72 )$$

This input to Multiply and Sum is s₅(x). The other input to Multiply and Sum is the Input Vector, ĉ(x) with unknown coefficients initialised, ĉ₅=0 and ĉ₇=0. The output of Multiply and Sum is 1.45+1.09j which is input to the multiplier. Select B selects from s₅(x) the coefficient of x³ which is −0.41−j. This is negated and inverted to produce 0.35−0.85j which is also input to the multiplier. As shown in FIG. 3, the result of the product, which in this case is 1.45-0.85j, is used by Update to update the coefficient ĉ₅ of the Input Vector.

For λ₂=7, Controller uses Select A to select the polynomial coefficient vectors α⁰, αⁱ−α⁸⁻⁴ and αⁱ−α⁸⁻⁵ corresponding to u₀(x), u₁(x) and u₂(x). These are stored in each respective Register and multiplied together to produce s₇(x):

$${s}_{7} ( x ) = ( 3.41 - 1.41 j ) + ( 2.41 + j ) x + ( 0.41 + j ) {x}^{2} - ( 1 + 0.41 j ) {x}^{5} - ( 1 + 2.41 j ) {x}^{6} + ( 1.41 - 3.41 j ) {x}^{7} \qquad ( 73 )$$

s₇(x) is input to Multiply and Sum. The other input to Multiply and Sum is the Input Vector, ĉ(x) with unknown coefficient initialised, ĉ₇=0. The output of Multiply and Sum is −3.65+2.27j which is input to the multiplier. Select B selects from s₇(x) the coefficient of x which is 2.41+j which is negated and inverted to produce −0.35+0.14j which is also input to the multiplier. As shown in FIG. 3, the result of the product, which in this case is 0.96−1.34j, is used by Update to update the coefficient ĉ₇ of the Input Vector to produce the original codeword.

$$c ( x ) = \hat{c} ( x ) = ( 0.27 - 0.01 j ) - ( 2.70 + 0.34 j ) x + ( 1.61 + 1.79 j ) {x}^{2} + ( 0.41 - 0.63 j ) {x}^{3} - ( 0.72 - 0.28 j ) {x}^{4} + ( 1.45 - 0.85 j ) {x}^{5} - ( 1.28 - 1.1 j ) {x}^{6} + ( 0.96 - 1.34 j ) {x}^{7}$$

### REFERENCES

[1] F. J. MacWilliams and N. J. A. Sloane, The Theory of Error Correcting Codes, North Holland, 1977
[2] S. Lin and D. J. Costello, Jr., Error Control Coding, 2^{nd} ed., Pearson Prentice Hall, 2004
[3] J. G. Proakis, Digital Communications, McGraw-Hill, 1997
[4] B. G. Dorsch, A Decoding Algorithm for Binary Block Codes and J-ary Output Channels, IEEE Transactions Information Theory, Vol. IT-20, pp. 391-394, May 1974.
[5] M. P. C. Fossorier and S. Lin, Soft-decision decoding of linear block codes based upon ordered statistics, IEEE Transactions Information Theory, Vol. 41, pp. 1379-1396, September 1995.
[6] M. Tomlinson, C. J. Tjhai, and M. A. Ambroze, Extending the Dorsch decoder towards achieving maximum-likelihood decoding for linear codes, IET Communications, Vol. 1, issue 3, pp. 479-488, June 2007.
[7] B. Kamali and P. Morris, Application of erasure-only decoded Reed-Solomon codes in cell recovery for congested ATM networks, pp. 982986, Vehicular Technology Conference 2000
[8] L. Rizzo, Effective erasure codes for reliable computer communication protocols, ACM Computer Communication review, vol. 27, pp. 2436, April 1997.
[9] A. J. McAuley, Reliable broadband communication using a burst erasure correcting code, Proc. ACM SIGCOMM 90; (Special Issue Computer Communication Review), September 1990, pp. 297306, published as Proc. ACM SIGCOMM 90; (Special Issue Computer Communication Review), volume 20, number 4.

What is claimed is:

1. A system in which a codeword from an error correcting code with minimum Hamming distance d has symbols in which the positions of d−1 of the parity check symbols may be arbitrarily chosen,
and each of the d−1 parity check symbols is produced by solving a parity check equation that is independent of all of the other parity check symbols and formed by multiplying together d−1 codewords from the dual code of the error correcting code, symbol by symbol,
starting with a codeword of the dual code that has a non zero symbol in the position of the parity check symbol being solved,
and in which each of the other d−2 dual code codewords comprise symbols given by the difference between an incrementally increasing power of a primitive root of unity and the primitive root of unity raised to a power equal to the position of each of the other d−2 parity check symbols,
and a total of d−1 parity check equations are so formed in parallel and used simultaneously to solve for the d−1 parity check symbols which together with the information symbols form an encoded codeword.

2. A system in which a codeword from an error correcting code with minimum Hamming distance d has symbols in which the positions of d−1 of the parity check symbols may be arbitrarily chosen,
and one of the d−1 parity check symbols is produced by solving a parity check equation that is independent of all of the other parity check symbols and formed by multiplying together d−1 codewords from the dual code, symbol by symbol,
and each of the d−1 parity check equations resulting from each dual code codeword multiplication is retained in the order they are calculated,
starting with an initial codeword of the dual code that has a non zero symbol in the position of the parity check symbol being solved,
and in which each of the other d−2 dual code codewords comprise symbols given by the difference between an incrementally increasing power of a primitive root of unity and the primitive root of unity raised to a power equal to the position of one of the other parity check symbols taken in turn,
and the resulting parity check equation is used to solve the parity check symbol,
and the solved parity check symbol is appended with the information symbols to form a partially solved codeword,
and each of the retained parity check equations are used in reverse order on the partially solved codeword to solve for each of the other parity check symbols in turn with each solved parity check symbol substituted into the partially solved codeword to update the partially solved codeword,
until the parity check equation corresponding to the initial codeword of the dual code is used to solve the last parity check symbol which is substituted into the partially solved codeword to form the encoded codeword.

3. A system in which e correctable symbols of a codeword from an error correcting code are unknown,
and each of the e unknown symbols is determined by solving a parity check equation that is independent of all of the other unknown symbols and formed by multiplying together e codewords from the dual code of the error correcting code, symbol by symbol,
starting with a codeword of the dual code that has a non zero symbol in the position of the unknown symbol being solved,
and in which each of the other e−1 dual code codewords comprise symbols given by the difference between an incrementally increasing power of a primitive root of unity and the primitive root of unity raised to a power equal to the position of each of the other e−1 unknown symbols,
and a total of e parity check equations are so formed in parallel and used simultaneously to solve for the e unknown symbols which together with the known symbols form the original codeword.

4. A system in which e correctable symbols of a codeword from an error correcting code are unknown,
and a parity check equation for one unknown symbol is produced that is independent of all of the other e−1 unknown symbols by multiplying together e codewords from the dual code of the error correcting code, symbol by symbol,
and where each of the e parity check equations resulting from each dual code codeword multiplication are retained in the order they are calculated,
starting with an initial codeword of the dual code that has a non zero symbol in the position of the unknown symbol being solved,
and in which each of the other e−1 dual code codewords are formed from the difference between an incrementally increasing power of a primitive root of unity and the primitive root of unity raised to a power equal to the position of each of the other unknown symbols taken in turn,
and the resulting parity check equation is used to solve the unknown symbol,
and the solved unknown symbol is appended with the known symbols to form a partially solved codeword,
and each of the retained parity check equations are used in reverse order on the partially solved codeword to solve for each of the other unknown symbols in turn with each solved symbol substituted into the partially solved codeword to update the partially solved codeword,
until the parity check equation corresponding to the initial codeword of the dual code is used to solve the last unknown symbol which is substituted into the partially solved codeword to form the original codeword.

5. A system according to claim 1 in which the symbols of the error correcting code and dual code are from the field of complex numbers.

6. A system according to claim 2 in which the symbols of the error correcting code and dual code are from the field of complex numbers.

7. A system according to claim 3 in which the symbols of the error correcting code and dual code are from the field of complex numbers.

8. A system according to claim 4 in which the symbols of the error correcting code and dual code are from the field of complex numbers.

9. A system according to claim 1 except that some products of dual code codewords, symbol by symbol, are not calculated as required but are pre-calculated and stored in memory in one or more look up tables,
and the required dual code codewords are accessed from the sets of dual code codewords stored in one or more look up tables.

10. A system according to claim 2 except that some products of dual code codewords, symbol by symbol, are not calculated as required but are pre-calculated and stored in memory in one or more look up tables,
and the required dual code codewords are accessed from the sets of dual code codewords stored in one or more look up tables.

11. A system according to claim 3 except that some products of dual code codewords, symbol by symbol, are not calculated as required but are pre-calculated and stored in memory in one or more look up tables,
and the required dual code codewords are accessed from the sets of dual code codewords stored in one or more look up tables.

12. A system according to claim 4 except that some products of dual code codewords, symbol by symbol, are not calculated as required but are pre-calculated and stored in memory in one or more look up tables,
and the required dual code codewords are accessed from the sets of dual code codewords stored in one or more look up tables.
